(19) United States
(12) Patent Application Publication
(10) Pub. No.: US 2023/0353130 A1
(43) Pub. Date: Nov. 2, 2023

(54) GENERATION OF QUANTUM RANDOM NUMBERS FROM SINGLE-PHOTON AVALANCHE DIODES

(71) Applicant: QRYPT, INC., New York, NY (US)

(72) Inventor: Denis MANDICH, New York, NY (US)

(73) Assignee: QRYPT, INC., New York, NY (US)

(21) Appl. No.: 17/733,695

(22) Filed: Apr. 29, 2022

(51) Int. Cl. H03K 3/84; H03K 17/92; H03K 19/21; H03K 3/037

(52) U.S. Cl. CPC H03K 3/84; H03K 17/92; H03K 19/21; H03K 3/037

(57) ABSTRACT

A system and method for random number generation. The method includes receiving, at a first single-photon avalanche diode (SPAD), a first series of photons, converting, by the first SPAD, the first series of photons into a first series of electrical pulses comprising a first random time interval between each pulse of the first series of electrical pulses, and outputting, by an output circuit in communication with the first SPAD, a random binary stream based at least in part on the first series of electrical pulses. A system is provided for generating random numbers including one or more SPADs, one or more associated quenching circuits, and output electronics configured to adjust thresholds, combine signals generated by an array of SPADS, condition signals, and output a stream of generated random numbers.

### FIELD OF THE INVENTION

This invention relates to random number generation and associated encryption of communications, and the creation and use of unique keys based on the generated random numbers.

### BACKGROUND

Datastores and computing devices are increasingly becoming the target of hackers who find new ways to exploit security vulnerabilities. A basic defensive tactic to thwart unauthorized access to data is to use encryption to render the data inaccessible if compromised or stolen. The foundation of all cryptography relies on the ability to produce a random number cryptographic key. In asymmetric cryptography, also known as public-key cryptography, public and private keys are used to encrypt and decrypt data. The keys are large numbers that have been paired together but are not identical (asymmetric). In some cases, random numbers are used to generate session keys, thus randomness is important to ensure the security of a system. Unfortunately, many encryption algorithms are not based on truly random numbers, but rather, on a predictable pattern. If a random generator produces an output with a predictable pattern or variance, it can be reverse-engineered.

The development of hardware random number generators that utilize a natural entropy source as a random seed number has led scientists to question the “randomness” or “quantumness” of some of the associated technological claims for such devices. All modern electronics are quantum at some level, even though the randomness they generate could be considered classical noise.

The source for the generation of quantum random numbers must be a quantifiable and measurable source of entropy. Quantum measurements have intrinsic unknowns as captured in the famous Heisenberg Uncertain Principle, which shows quantum systems are probabilistic at a fundamental level. Further work explained in Bell's Theorem proves quantum randomness is intrinsic to quantum measurements and not the result of hidden or unknown variables determining the outcome.

It is difficult to build quantum electronic systems to separate quantum signals from classical noise. This difficulty is more pronounced in the variations found in modern manufacturing techniques, especially at the microchip level. The control, accounting, and measurement of these signals are the critical difference between the illusion of randomness and actual quantum randomness. A need still exists for an improved quantum random number generator.

### SUMMARY

The disclosed technology provides systems and methods for generating random numbers which can be used for encryption keys.

In accordance with certain exemplary implementations of the disclosed technology, a method is provided for generating a random number. The method includes receiving, at a first single-photon avalanche diode (SPAD), a first series of photons, converting, by the first SPAD, the first series of photons into a first series of electrical pulses comprising a first random time interval between each pulse of the first series of electrical pulses, and outputting, by an output circuit in communication with the first SPAD, a random binary stream based at least in part on the first series of electrical pulses.

Certain exemplary implementations of the disclosed technology include a quantum random number generator. The quantum random number generator includes one or more single-photon avalanche diodes (SPADs), each of the SPADS configured to receive a corresponding series of photons, one or more quenching circuits in communication with each corresponding one or more SPADs, the one or more quenching circuits configured to convert the corresponding series of photons into the corresponding series of electrical pulses, each corresponding series of electrical pulses comprising corresponding random time intervals between each pulse of the corresponding series of electrical pulses, and an output circuit in communication with one or more quenching circuits, the output circuit configured to output a random binary stream based at least in part on the corresponding series of electrical pulses.

Further features of the disclosed design and the advantages offered thereby are explained in greater detail hereinafter regarding specific embodiments illustrated in the accompanying drawings, wherein like elements are indicated to be like reference designators.

### BRIEF DESCRIPTION OF THE DRAWINGS

The above and further aspects of this invention are further discussed with reference to the following description in conjunction with the accompanying drawings, in which like numerals indicate like structural elements and features in various figures. The drawings are not necessarily to scale, emphasis instead being placed upon illustrating principles of the invention. The figures depict one or more implementations of the inventive devices, by way of example only, not by way of limitation.

FIG. 1A illustrates an example SPAD-based system for random number generation, in accordance with an embodiment of the present disclosure.

FIG. 1B illustrates another example SPAD-based random number generation system with a quenching circuit, in accordance with an embodiment of the present disclosure.

FIG. 1C is a diagram of various input pulses for generating an output signal of an example device of FIG. 1A or 1B based on a series of photons received at the SPAD, in accordance with an embodiment of the present disclosure.

FIG. 2A illustrates an example device having an array of SPADs, in accordance with an embodiment of the present disclosure.

FIG. 2B is a diagram of various input pulses for generating an input signal of an example array of SPADs of FIG. 2A based on a series of photons received at the array of SPADs, in accordance with an embodiment of the present disclosure.

FIG. 3A illustrates voltage threshold control of an output circuit, in accordance with an embodiment of the present disclosure.

FIG. 3B illustrates another voltage threshold control of an output circuit, in accordance with an embodiment of the present disclosure.

FIG. 3C illustrates yet another voltage threshold control of an output circuit, in accordance with an embodiment of the present disclosure.

FIGS. 4A illustrates an example of random binary stream output based on input voltage threshold control of an output circuit, in accordance with an embodiment of the present disclosure.

FIG. 4B illustrates an example of random binary stream output based on input voltage threshold control of an output circuit, in accordance with an embodiment of the present disclosure.

FIG. 5 illustrates an example random flip-flop (RFF) circuit with a voltage threshold control input, in accordance with an embodiment of the present disclosure.

FIG. 6 illustrates another example of random binary stream output, in accordance with an embodiment of the present disclosure

FIG. 7 is a flow diagram of a method, in accordance with certain exemplary implementations of the disclosed technology.

### DETAILED DESCRIPTION

The disclosed technology includes methods and systems for the generation of random numbers by controlling quantum microelectronics to produce truly random numbers. The system and method described herein may rely on the randomness of photons, a low detector efficiency of a diode, and threshold voltage regulation of an output circuit to generate a random binary stream. Certain example devices, systems, and methods presented herein can allow for entropy harvesting and random number generation.

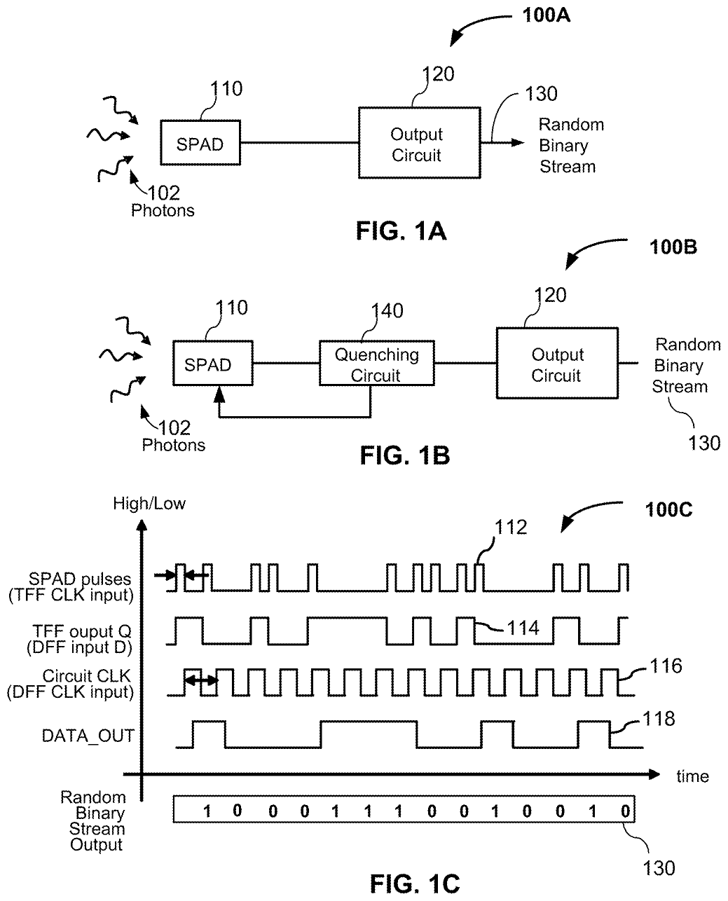

FIG. 1A illustrates an example system 100A for random number generation, in accordance with an embodiment of the present disclosure. The system 100A may utilize a single-photon avalanche diode (“SPAD”) 110 to detect incident photons 102. The term “SPAD” defines a class of photodetectors able to detect low-intensity photon radiation (down to the single-photon) and to signal the time of the photon arrival with high temporal resolution (a few tens of picoseconds). SPADs are semiconductor devices based on a p-n junction reversed biased at a voltage higher than the breakdown voltage. SPADs behave like an Avalanche photodiode (APD) by exploiting a photon-triggered avalanche current to detect incident radiation.

The fundamental difference between SPADs and APDs is that SPADs are specifically designed to operate with a reverse bias voltage well above the breakdown voltage while APDs typically operate at a bias lesser than the breakdown voltage. Under the high reverse bias, the electric field in the p-n junction of the SPAD is high enough that a single charge carrier injected in the depletion layer (as a result of an incoming photon) can trigger a self-sustaining avalanche. Once triggered, the resulting “avalanche” current rises swiftly to a steady level.

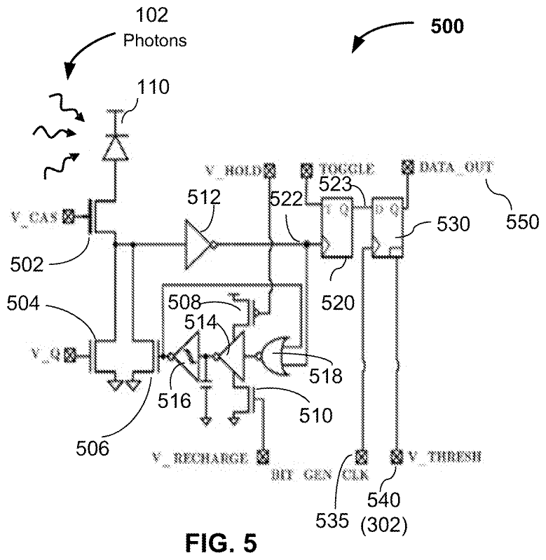

In accordance with certain exemplary implementations of the disclosed technology, the output of the SPAD 110 may be further conditioned/controlled by an output circuit 120 in communication with the SPAD 110. The output circuit 120 may output a random binary stream 130, that may be used as a random number seed (or sequence) for encryption. The random binary stream 130 can, for example, then be used for communication technology, cryptographic software, hardware, or any combination thereof. In certain exemplary implementations, the output circuit 120 may include an adjustable voltage threshold control input (as will be discussed further below with reference to FIG. 5).

FIG. 1B illustrates another example SPAD-based random number generation system 100B with a quenching circuit 140, in accordance with an embodiment of the present disclosure. However, in certain implementations, the quenching circuit may be packaged with the SPAD 110 or the output circuit 120. As discussed above, once the incoming photon(s) 102 triggers the self-sustaining avalanche in the SPAD 110, the current continues to flow until the avalanche current is quenched by lowering the bias voltage down to (or below) the breakdown voltage. In order to be able to detect another photon, the bias voltage is raised again above breakdown. The quenching circuit 140 may be utilized to handle such trigger detection and bias control.

In certain exemplary implementations, the quenching circuit 140 may sense the leading edge of the avalanche current that is output from the SPAD 110. In certain exemplary implementations, the quenching circuit 140 may generate a standard output pulse synchronous with the avalanche build-up. In certain implementations, the quenching circuit 140 may quench the avalanche by lowering the bias voltage of the SPAD 110 down to (or below) the breakdown voltage, which may “reset” the SPAD 110 to enable detection of a subsequently arriving photon 102. In accordance with certain exemplary implementations of the disclosed technology, the SPAD 110 may be selectively reset after the photon has triggered the avalanche (or not) to synchronize photon detection (or not) with clock-based and/or adjustable decision thresholds.

The disclosed technology can exploit the random nature in which each photon received by the SPAD 110 is received at a random time interval. The impact of the first series of photons 102 on the SPAD 110, for example, triggers a current avalanche, which may be in the form of exponential growth of charge carriers. The first series of photons 102 incident on the SPAD 110 may then be converted into a first series of electrical pulses. The first series of electrical pulses can comprise a first random time interval between each pulse of the first series of pulses. The output circuit 120 may receive the first series of electrical pulses and may generate a random binary stream 130 based at least in part on the first series of electrical pulses.

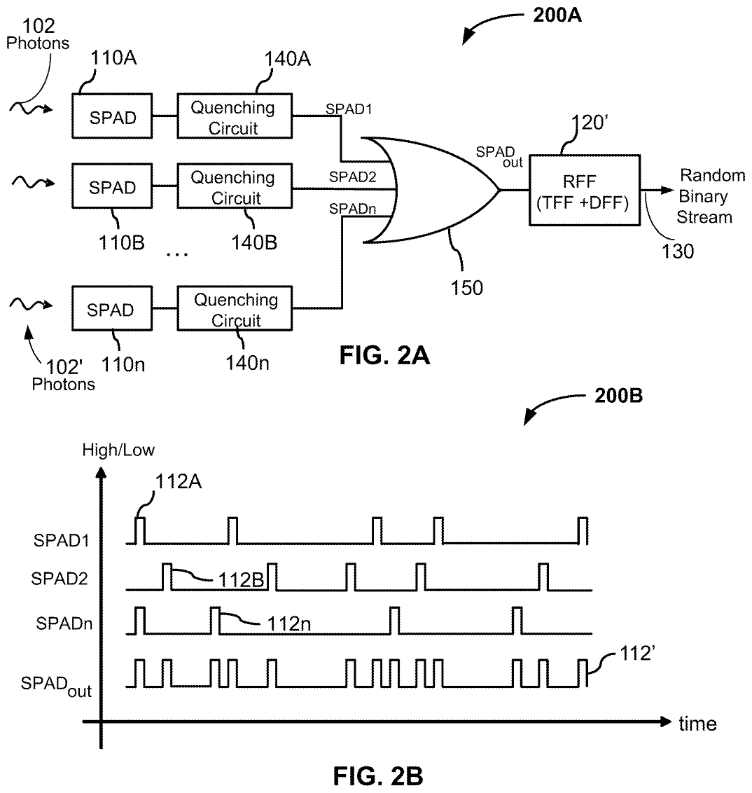

In accordance with certain exemplary implementations of the disclosed technology, SPADs 110 can be combined in any number of geometries including 2D and 3D arrays (as will be discussed with respect to FIG. 2A below). The output circuit 120 can include other inputs and/or outputs. For example, the random binary stream 130 generated by the output circuit 120 may be controlled or manipulated by an input threshold control voltage.

As will be discussed below with reference to FIG. 5, output circuit 120 can include AND gates, OR gates, XOR gates, NOT gates, inverters, Schmidt triggers, NAND gates, NOR gates, XNOR gates, EXOR gates, EXNOR gates, multiplexers, flip-flops, and other logical gates, or combinations thereof.

As discussed above, FIG. 1B further illustrates a device 100B comprising of a SPAD 110, an output circuit 120, and a quenching circuit 140 in electrical communication with the SPAD 110 and the output circuit 120. In certain exemplary implementations, the SPAD 110 may comprise a p-n junction that, when actively detecting photons, operates at a bias voltage that is above the p-n junction breakdown voltage. At such bias voltage, the electric field can be high enough that a single charge carrier injected into the depletion layer (via reception of a photon, for example) can trigger a self-sustaining avalanche. The resulting current may rise swiftly to a steady level and may continue to flow until the avalanche can be quenched by the quenching circuit 140 by lowering the bias voltage to the breakdown voltage or below. Thereafter, the bias voltage may be restored by the quenching circuit 140 and the SPAD 110 and associated circuitry may then be used to detect another photon, and the process may repeat.

In certain exemplary implementations, the quenching operation may use a suitable quenching circuit 140 that can perform one or more of the following: (a) sense the leading edge of the avalanche current; (b) generate a standard output pulse that is well synchronized to the avalanche rise; (c) quench the avalanche by lowering the bias to the breakdown voltage (or below); and/or (d) restore the SPAD bias voltage to the operating level.

In accordance with certain exemplary implementations of the disclosed technology, the SPAD 110 may detect a first series of photons 102 that impact the SPAD 110. The quenching circuit 140 may then convert the first series of photons 102 into the first series of electrical pulses. The waiting time between the rising edge of the electrical pulses can be random with an exponential probability distribution function. In certain exemplary implementations, the quenching circuit 140 may also generate a randomized clock pulse input based at least in part on the first series of electrical pulses. In certain exemplary implementations, the quenching circuit 140 may include other inputs, outputs, AND gates, OR gates, XOR gates, NOT gates, NAND gates, NOR gates, XNOR gates, EXOR gates, EXNOR gates, multiplexers, and other logical gates, or combinations thereof. The output circuit 120 may receive the randomized clock pulse input and generate a random binary stream 130 based at least in part on the first series of electrical pulses.

In some embodiments, the dead time between quenches of the SPAD 110 or quenching circuit 140 can be varied to ensure unbiased operation. In other embodiments, another control point to ensure the unbiased operation can include asynchronous operation of the SPAD 110, quenching circuit 140, output circuit 120, state measurements, flip-flops, and logical gates of the quenching circuit 140 and output circuit 120 by using different clocks and combinations of clocks.

FIG. 1C illustrates a time-diagram 100C of various pulses associated with input pulses for generating an output signal of an example device of FIG. 1A or 1B based on a series of photons 102 received at the SPAD 110. This example time-diagram 100C is based on a SPAD, a quenching circuit, and an output circuit (such as output circuit 120 as discussed above with reference FIG. 1A or 1B, or as will be discussed below with reference to FIG. 5). For example, the output circuit can include a toggle flip-flop and a data flip-flop. A flip-flop is a basic circuit element capable of storing two states, controlled by an input signal. A random flip-flop is a circuit that performs an action when a clock pulse input changes state from low to high. The output of the random flip-flop can be separately clocked, and bits can be sampled to produce a random binary stream 130 of ones and zeros. In some embodiments, the output circuit 120 can include flip-flops, inputs, outputs, AND gates, OR gates, XOR gates, NOT gates, NAND gates, NOR gates, XNOR gates, EXOR gates, EXNOR gates, multiplexers, and other logical gates, flip-flops or circuits, or combinations thereof.

As depicted in FIG. 1C, each of the SPAD pulses 112 (toggle flip-flop clock inputs) are characterized by leading-edge and falling edge. The toggle flip-flop produces an output Q signal 114 responsive to the SPAD pulses 112. The Q signal 114 may be fed into the data flip-flop as an input. As illustrated in FIG. 1C, the toggle flip-flop output Q signal 114 is toggled high and low by the leading edges of the SPAD pulses 112. A circuit clock signal 116 may be fed into the data flip-flop clock input, and the data flip-flop may generate a DATA_OUT signal 118. In accordance with certain exemplary implementations of the disclosed technology, the DATA_OUT signal 118 output from the data flip-flop may be used to generate the random binary stream output 130. In certain exemplary implementations, the DATA_OUT signal 118 of the data flip-flop may be separately clocked. In some implementations, for example, every rising edge of the DATA_OUT signal 118 may result in an output of “1” in the random binary stream output 130. Conversely, every falling edge of the DATA_OUT signal 118 may result in an output of “0” in the random binary stream output 130. If the state of the DATA_OUT signal 118 remains unchanged, then the previous state may be output to the random binary stream output 130. In other words, the DATA_OUT signal 118 can be sampled to produce the random binary stream 130 of ones and zeros as depicted in FIG. 1C.

FIG. 2A illustrates a system 200A having an array of SPADs (110A, 110B, . . . , 110n) with corresponding quenching circuits (140A, 140B, . . . , 140n) providing corresponding n SPAD signals (SPAD1, SPAD2, . . . , SPADn) that may be input to an OR gate 150 to produce a randomized clock pulse input (SPADout) for the output circuit 120. Here, each respective SPAD (110A, 110B, . . . , 110n) of the array may detect their own respective series of photons 102 from a multiple series of photons 102-102′ (as discussed above with respect to FIGS. 1A and 2A). The series of corresponding quenching circuits (140A, 140B, . . . , 140n) may be utilized in conjunction with the corresponding SPADs (110A, 110B, . . . , 110n) to detect and convert each series of photons 102, 102′ into their respective series of electrical pulses.

In accordance with certain exemplary implementations of the disclosed technology, various circuits and/or gates may be used to combine the signals from the array of SPADs (110A, 110B, . . . , 110n) to output a single randomized clock pulse input (SPADout) to the output circuit 120′ as discussed above. Other logical gates, including, but not limited to, AND gates, OR gates, XOR gates, NOT gates, NAND gates, NOR gates, XNOR gates, EXOR gates, EXNOR gates, multiplexers, and other logical gates, or combinations thereof, can be used to combine the signals from each of quenching circuits (140A, 140B, . . . , 140n). The single randomized clock pulse input can be fed into the output circuit 120′ that can include one or more flip-flops and/or other logical circuit equivalents to generate a random binary stream 130 based at least in part on the randomized clock pulse input (SPADout). In some examples, the single randomized clock pulse input (SPADout) may be fed into a series of flip-flops to generate the random binary stream 130.

The output circuit 120′, as illustrated in FIG. 2A can include a random flip-flop that may include one or more toggle flip-flops and one or more data flip-flops. The output circuit 120′ may further include an analog to digital converter.

In some embodiments, control points may be included in the systems 100A, 100B, and/or 200A to ensure unbiased operation, for example, by varying or switching on and off light intensity on a SPAD 110 or an array of SPADs (110A, 110B, . . . , 110n). In certain exemplary implementations, blocks of SPAD sub-arrays may be utilized to provide differential distribution of illumination over the array with multiple sources. In certain embodiments, continuous health checks can be run on the SPAD 110 or an array of SPADs (110A, 110B, . . . ,110n) to measure the variability of response, dark counts, jitter, correlations, defects, and toggling them on or off. Dark count is the average rate of registered counts without any incident light on a SPAD 110. A health check on the jitter timing of a SPAD 110 can help determine the fast temporal response behavior of the SPAD 110. By ensuring the overall health of the array of SPADs (110A, 110B, . . . ,110n), the unbiased operation of the random number generator can be verified. In other examples, to ensure the unbiased operation of the random number generator, the array of SPADs (110A, 110B, . . . ,110n), may be arranged in a grid and continuously monitored for bias using columns, rows, or any combination to identify nonrandom behavior. If an individual SPAD 110 in an array of SPADs (110A, 110B, . . . ,110n) is malfunctioning, the nonrandom behavior of the individual SPAD 110 can be identified by comparing the output of the individual SPAD 110 to neighboring SPADs (110A, 110B, . . . ,110n), which may be another control point to ensure unbiased operation.

FIG. 2B illustrates a time-diagram 200B of various pulses associated with generating an output signal of the OR gate 150 based on a series of photons 102 102′ received at the SPADs (110A, 110B, . . . , 110n). In this diagram, each SPAD in the array of SPADs (110A, 110B, . . . , 110n) has a corresponding pulse train (112A, 112B, . . . ,112n) with a leading and falling edge. As illustrated in FIG. 2A, the series of electrical pulses from each of the corresponding quenching circuits (140A, 140B, . . . , 140n) may input to the OR gate 150 to result in a combined output 112′ that may be used as a single randomized clock pulse input to the output circuit 120′. Other logical gates, including, but not limited to, AND gates, OR gates, XOR gates, NOT gates, NAND gates, NOR gates, XNOR gates, EXOR gates, EXNOR gates, multiplexers, and other logical gates, or combinations thereof, can be used to combine the multiple-input pulse trains (112A, 112B, . . . ,112n) to the combine output 112'. In this example, every leading and falling edge of each SPAD in the array of SPADs (110A, 110B, . . . ,110n) is included as a leading and falling edge in the combined output 112′.

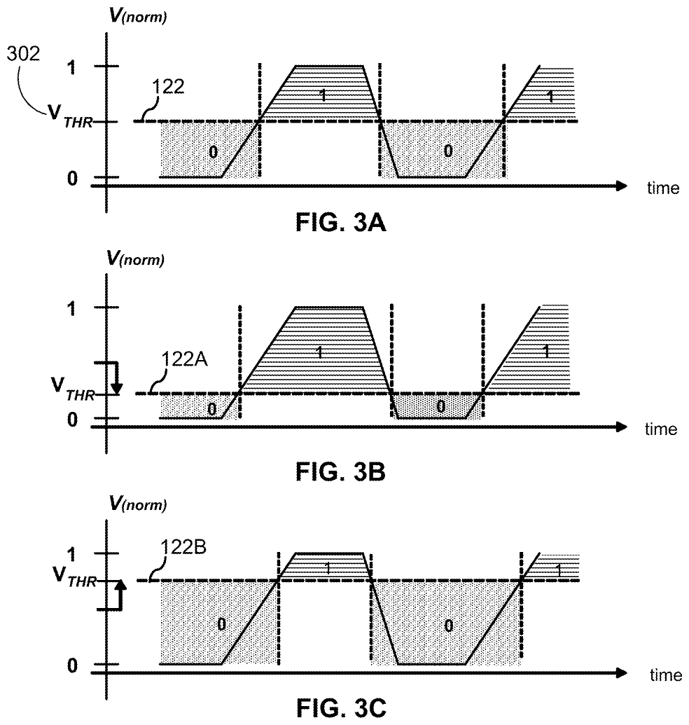

FIGS. 3A through 3C illustrate various implementations of setting a threshold voltage V_{THR} 302 to control the threshold voltage level(s) (122, 122A, 122B) for which the output circuit (such as output circuit 120 shown in FIG. 1A and/or FIG. 1B and/or output circuit 120′ shown in FIG. 2A) interprets the corresponding input signal received from the SPAD(s) and/or other combining logic (such as the OR gate 150 shown in FIG. 2A) as a binary 0 or 1 for output.

FIG. 3A, for example, illustrates the voltage threshold V_{THR} 302 set to approximately 50% of the normalized input voltage V(norm) full range so that input voltage below the set threshold voltage level 122 is interpreted as a 0, while input voltage above the set threshold voltage level 122 is interpreted as a 1.

FIG. 3B, for example, illustrates the voltage threshold V_{THR} 302 set to approximately 25% of the normalized input voltage V(norm) full range so that input voltage below the set threshold voltage level 122A is interpreted as a 0, while input voltage above the set threshold voltage level 122A is interpreted as a 1.

FIG. 3C, for example, illustrates the voltage threshold V_{THR} 302 set to approximately 75% of the normalized input voltage V(norm) full range so that input voltage below the set threshold voltage level 122B is interpreted as a 0, while input voltage above the set threshold voltage level 122B is interpreted as a 1.

In accordance with certain exemplary implementations of the disclosed technology, and as illustrated in FIGS. 3A through 3C, the input signal (from the SPADs, etc.) may have an associated slew rate (i.e., rise or fall level that is not instantaneous), so adjusting the voltage threshold V_{THR} 302 may alter the associated time durations of the output 1s and 0s, which can provide a controllable method for further randomizing decision points for when input from one or more SPADs is interpreted as a 0 or 1 for output. In certain exemplary implementations, the V_{THR} 302 can be controlled based on a randomized input, including but not limited to an output of one or more SPADs.

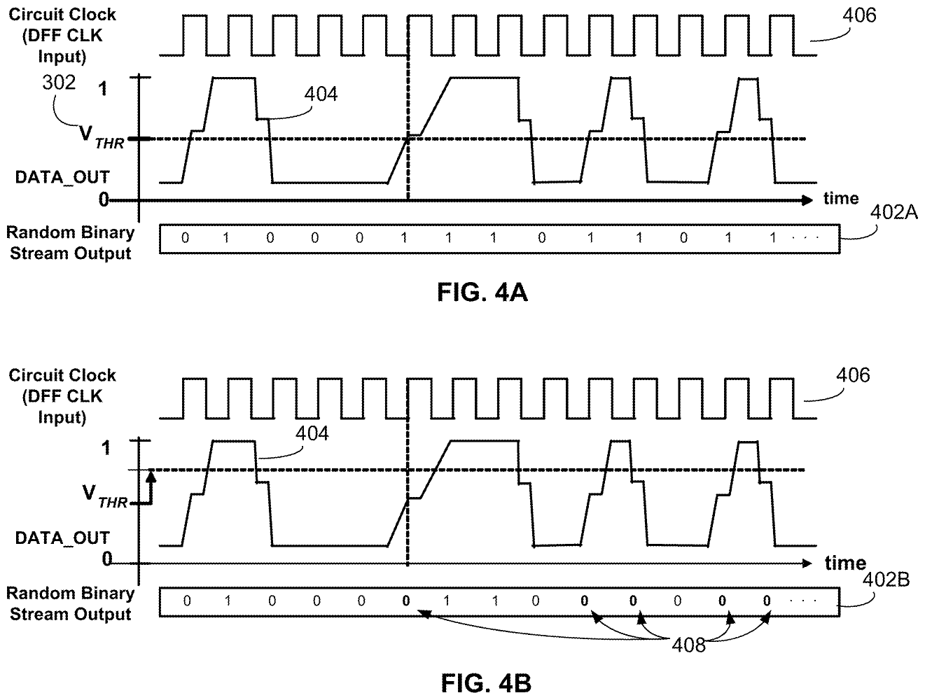

FIG. 4A and FIG. 4B further illustrates examples of how the voltage threshold V_{THR} 302 can affect the random binary stream output 402A 402B based on toggled voltage threshold control input. FIG. 4A, for example, illustrates the voltage threshold V_{THR} 302 set to approximately 50% of the normalized input voltage full range so that input voltage 404 below the set voltage threshold V_{THR} 302 is interpreted (at each rising edge of the clock signal 406) as a 0, while input voltage above the set threshold voltage level 122 is interpreted (at each rising edge of the Circuit Clock signal 406) as a 1. FIG. 4B, for example, illustrates the voltage threshold V_{THR} 302 set to approximately 75% of the normalized input voltage full range so that input voltage 404 below the set voltage threshold V_{THR} 302 is interpreted (at each rising edge of the clock signal 406) as a 0, while input voltage 404 above the set threshold voltage level 122 is interpreted (at each rising edge of the clock signal 406) as a 1. A comparison of the random binary stream outputs 402A 402B show a difference in certain bits 408 between the two random binary stream outputs 402A 402B as a function of the voltage threshold V_{THR} 302. In certain exemplary implementations, the voltage threshold V_{THR} 302 can be controlled based on a randomized input (including but not limited to an output of one or more SPADs) to further randomize (an already randomized) binary stream output. In this respect, the voltage threshold V_{THR} 302 may provide a desired additional level of randomization in the random number generator. In certain exemplary implementations, the voltage threshold V_{THR} 302 may be set to control the ratio of 0s and 1s in the randomized binary stream output 402A 402B over a period.

FIG. 5 illustrates an example circuit 500 (including a SPAD 110) with various circuit components that can be utilized to provide a DATA_OUT output 550 (i.e., a randomized binary stream output) base on receiving (and detecting) photons 102 by the SPAD 110. While other circuit components, arrangements, and/or control inputs may be utilized, the circuit 500 illustrates an example embodiment that may be utilized in a practical application. The example circuit 500 can include one or more field-effect transistors 502 504 506 510, one or more inverters 512 514, one or more Schmitt triggers 516, one or more NOR gates 518, one or more toggle flip-flops 520, and/or one or more data flip-flops 530. In accordance with certain exemplary implementations of the disclosed technology, the circuit 500 illustrated in FIG. 5 may be considered as a random flip-flop (RFF) circuit with a voltage threshold control input V_THRESH 504 (for example, the voltage threshold control input may be similar or equivalent to the voltage threshold V_{THR} 302 as described above). The RFF circuit may also include various quenching control inputs V_CAS, V_Q, V_RECHARGE, V_HOLD, for example, that may be used to control the biasing and quenching of the SPAD 110, as discussed previously. The RFF circuit may also include other controls, such as the BIT GEN CLK (which may be similar or equivalent to the circuit clock 406 discussed with respect to FIG. 4A and FIG. 4B). A certain exemplary implementation can include a and/or TOGGLE input as an input to the toggle flip-flop 520. In certain implementations, the Q output of the toggle flip-flop 520 may be used as the data input of the data flip-flop 530. The arrangements and interactions among the various components of the circuit 500 may be understood by those having basic skills in the art of electronic circuits and logic design.

In accordance with certain exemplary implementations of the disclosed technology, photons 102 may be detected by the SPAD 110, which may, in turn, produce a signal that passes through a series of circuits and gates, (which may form a quenching circuit) to produce a randomized clock pulse input 522 into the toggle flip-flop 520. The toggle flip-flop 520 is a sequential logic circuit that toggles its output according to the input state. In this example, the output states of the toggle flip-flop 520 may be toggled high or low by the leading edges of the randomized clock pulse 522 from the SPAD 110 and/or associated quenching circuitry. The toggle flip-flop 520 may feed its output (Q) to the data input (D) of the data flip-flop 530. The data flip-flop 530 can then capture the input value at the specified edge of a clock signal CLK fed to the data flip-flop 520. A threshold voltage control input V_THRESH 540 can adjust the data flip-flop 530 to address the rise and fall times of the output from the toggle flip-flop 520. A regular oscillating clock signal may be used as the clock input CLK of the data flip-flop 530. The data flip-flop 530 can allow for the synchronization of the output of the toggle flip-flop 520 to a clock. The data output 550 of the data flip-flop 530 can be separately clocked and the corresponding output bits can be sampled to produce the random binary stream of ones and zeros (such as discussed above with respect to the random binary stream 130 in FIGS. 1A, 1B, 1C, 2, and/or the random binary stream 402A, 402B in FIGS. 4A and 4B.

In some embodiments, the reverse bias breakdown voltage of the SPAD 110 can be varied to modify and tune the randomized clock pulse input 522 into the toggle flip-flop 520.

In some embodiments, as discussed above, the threshold voltage V_THRESH (V_{THR} 302) or can be provided to control the random binary stream output 550 such that the ratio of 1s to 0s output in the random binary stream output 550 can be adjusted. For example, the ratio of 1s to 0s output in the random binary stream output 550 may be adjusted over a range of 0.01 to 100. In certain exemplary implementations, it may be desirable to set the ratio of 1s to 0s output in the random binary stream output 550 to be approximately 1 (i.e., 1:1) over a predetermined period. In certain exemplary implementations, an additional averaging circuit may be utilized to provide feedback to control the threshold voltage.

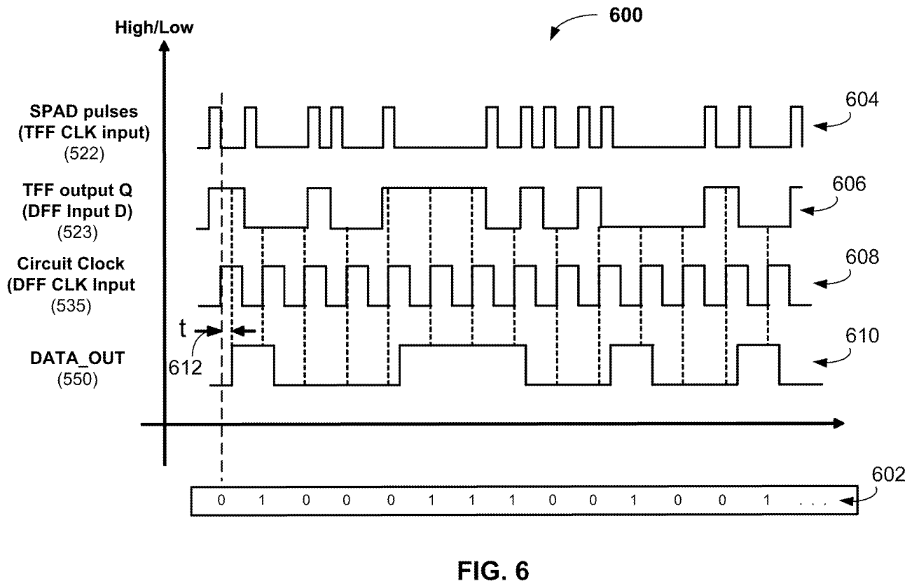

In certain exemplary implementations, instead of feeding the output 523 from the toggle flip-flop 520 into the data flip-flop 530, direct voltage measurements on the output 523 of the toggle flip-flop 530 can be used to generate the random binary stream 130. In other embodiments, the toggle-flip-flop 530 can be combined with analog to digital converters to produce the random binary stream 130. FIG. 6 is a timing diagram 600 illustrating the generation of a random binary stream output 602. Diagram 600 illustrates SPAD pulses 604 (which can correspond to the input 522 of the toggle flip-flop 520, as discussed in FIG. 5), a Q output 606 (which can correspond to the D input 523 of the data flip-flop 530, as discussed in FIG. 5), a clock signal 608, (which can correspond to the clock signal 535, as discussed in FIG. 5), and a DATA_OUT signal 610 (which may correspond to the DATA_OUT 550 as discussed in FIG. 5). Diagram 600 further illustrates that a delay t 612 that can be present (or set) for example, so that the timing of the evaluation of the SPAD pulses 604 happens after a predetermined time after the rising edge of the clock 608.

In certain exemplary implementations, and as illustrated in FIG. 6, the Q output 606 may toggle on each rising edge of the SPAD pulses 604. In certain exemplary implementations, the DATA_OUT signal 610 may be generated based on a combination of the Q output 606 logic level, the clock 608 logic level, and the delay t 612. Thus, according to certain exemplary implementations of the disclosed technology, the delay t 612 may be utilized to further alter or randomize the DATA_OUT 610 in comparison to the Q output 606.

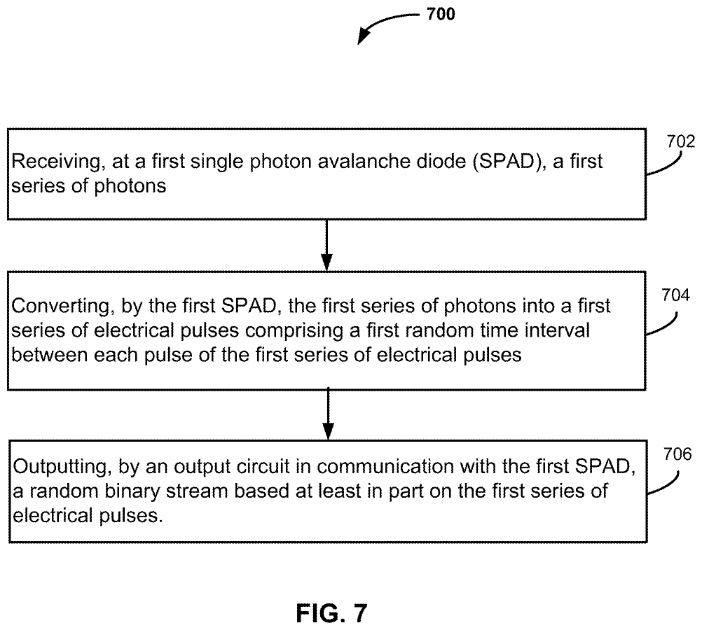

FIG. 7 is a flow diagram of a method 700, in accordance with certain exemplary implementations of the disclosed technology. In block 702, the method 700 includes receiving, at a first single-photon avalanche diode (SPAD), a first series of photons. In block 704, the method 700 includes converting, by the first SPAD, the first series of photons into a first series of electrical pulses comprising a first random time interval between each pulse of the first series of electrical pulses. In block 706, the method 700 includes outputting, by an output circuit in communication with the first SPAD, a random binary stream based at least in part on the first series of electrical pulses.

Certain exemplary implementations of the disclosed technology can include receiving, at a second single-photon avalanche diode (SPAD), a second series of photons. Some implementations can include converting, by the second SPAD, the second series of photons into a second series of electrical pulses comprising a second random time interval between each pulse of the second series of electrical pulses, and outputting, by the output circuit, a random binary stream based at least in part on the first series of electrical pulses and the second series of electrical pulses.

Certain exemplary implementations of the disclosed technology can include adjusting a bias voltage of the SPAD using a quenching circuit responsive to photon detection by the SPAD. In some implementations, the quenching circuit may be configured to convert the first series of photons into the first series of electrical pulses.

Certain exemplary implementations of the disclosed technology can include generating, by the quenching circuit, a randomized clock pulse based at least in part on the first series of electrical pulses.

In certain exemplary implementations, the output circuit can include one or more of a toggle flip-flop (TFF), a data flip-flop (DFF), a random flip-flop (RFF), an analog to digital converter (ADC), or combinations thereof. In certain exemplary implementations, the RFF can include a TFF and/or a DFF. In some implementations, an input to the TFF can be a randomized clock pulse input generated based at least in part on the first series of electrical pulses.

Certain exemplary implementations of the disclosed technology can include toggling an output of the TFF based on a leading edge of the randomized clock pulse input. Certain exemplary implementations of the disclosed technology can include toggling an output of the TFF based on a delay after the leading edge of the randomized clock pulse input. In some implementations, the output of the TFF may be provided as a data input to the DFF.

According to an exemplary implementation of the disclosed technology, a regularly oscillating clock signal may be provided to a clock input of the DFF.

In some implementations, the DFF can further include a voltage threshold control input.

Certain exemplary implementations of the disclosed technology can include adjusting a voltage threshold V_{THR} to control the input of the output circuit to cause the output circuit to output the random binary stream such that the random binary stream outputs a controllable ratio of 1's and 0's. In certain exemplary implementations, the V_{THR} may be controlled so that the average number of 0's the is output in the random binary stream is approximately equal to an average number of 1's.

Certain exemplary implementations of the disclosed technology can include adjusting a voltage threshold V_{THR} to control the input of the output circuit to cause the output circuit to output the random binary stream such that the random binary stream outputs an average number of 0's that is unequal to an average number of 1's.

Certain exemplary implementations of the disclosed technology can include emitting the first series of photons from a source in thermal equilibrium for detection by one or more SPADS. According to certain exemplary implementations of the disclosed technology, the source can include one or more of a light-emitting diode (LED), a pulsed laser, and a combination thereof. In certain exemplary implementations, the source can include ambient light.

Certain exemplary implementations of the disclosed technology can include digitizing, with an analog to digital converter (ADC), one or more of the first series of electrical pulses, and the random binary stream. Some implementations can include varying the dead time of receiving, at the SPAD, a first series of photons, wherein the first series of photons comprises a first random time interval between the arrival of each photon in the first series of photons.

Certain exemplary implementations of the disclosed technology can include receiving, at a second single-photon avalanche diode (SPAD), a second series of photons. Certain exemplary implementations of the disclosed technology can include converting, by the second SPAD, the second series of photons into a second series of electrical pulses comprising a second random time interval between each pulse of the second series of electrical pulses. Certain exemplary implementations of the disclosed technology can include outputting, by the output circuit, a random binary stream based at least in part on the first series of electrical pulses and the second series of electrical pulses. According to an exemplary implementation of the disclosed technology, the output circuit can include one or more of a NOT gate, an AND gate, a NAND gate, an OR gate, a NOR gate, an XOR gate, an XNOR gate, and a combinations thereof.

The disclosed technology includes a quantum random number generator that can include one or more single-photon avalanche diodes (SPADs), each of the SPADS configured to receive a corresponding series of photons, one or more quenching circuits in communication with each corresponding one or more SPADs, the one or more quenching circuits may be configured to convert the corresponding series of photons into the corresponding series of electrical pulses, each corresponding series of electrical pulses can include corresponding random time intervals between each pulse of the corresponding series of electrical pulses. The system can include an output circuit in communication with one or more quenching circuits. The output circuit may be configured to output a random binary stream based at least in part on the corresponding series of electrical pulses.

The descriptions contained herein are examples of embodiments of the disclosed technology and are not intended in any way to limit the scope of the invention. As described herein, the descriptions contemplate many variations and modifications of a random number generation system, including additional communication functionality, additional functionality to meet end-user needs not specifically described herein, additional and/or alternative random number sources, additional and/or alternative schemes and means for generating random bitstreams, additional and/or alternative schemes for encrypting and/or encapsulating random numbers for secure transfer over an unsecured network, additional and/or alternative schemes for creating virtual entropy sources, etc. These modifications would be apparent to those having ordinary skill in the art to which this invention relates and are intended to be within the scope of the claims which follow.

What is claimed is:

1. A method for generating a random number, comprising:
receiving, at a first single-photon avalanche diode (SPAD), a first series of photons;
converting, by the first SPAD, the first series of photons into a first series of electrical pulses comprising a first random time interval between each pulse of the first series of electrical pulses; and
outputting, by an output circuit in communication with the first SPAD, a random binary stream based at least in part on the first series of electrical pulses.

2. The method of claim 1, further comprising:
receiving, at a second single-photon avalanche diode (SPAD), a second series of photons;
converting, by the second SPAD, the second series of photons into a second series of electrical pulses comprising a second random time interval between each pulse of the second series of electrical pulses; and
outputting, by the output circuit, a random binary stream based at least in part on the first series of electrical pulses and the second series of electrical pulses.

3. The method of claim 1, further comprising adjusting a bias voltage of the SPAD using a quenching circuit responsive to photon detection by the SPAD.

4. The method of claim 3, wherein the quenching circuit is configured to convert the first series of photons into the first series of electrical pulses.

5. The method of claim 4, further comprising generating, by the quenching circuit, a randomized clock pulse based at least in part on the first series of electrical pulses.

6. The method of claim 1, wherein the output circuit comprises one or more of a toggle flip-flop (TFF), a data flip-flop (DFF), a random flip-flop (RFF), an analog to digital converter (ADC), or combinations thereof.

7. The method of claim 6, wherein the RFF comprises a TFF and a DFF.

8. The method of claim 7, wherein an input to the TFF comprises a randomized clock pulse input generated based at least in part on the first series of electrical pulses.

9. The method of claim 8, further comprising:
toggling an output of the TFF based on a leading edge of the randomized clock pulse input.

10. The method of claim 9, further comprising:
providing the output of the TFF as a data input to the DFF.

11. The method of claim 7, further comprising:
providing a regularly oscillating clock signal to a clock input of the DFF.

12. The method of claim 11, wherein the DFF further comprises a voltage threshold control input.

13. The method of claim 1, further comprising:
adjusting a voltage threshold V_{THR} to control input of the output circuit to cause the output circuit to output the random binary stream such that the random binary stream outputs an average number of 0's that is approximately equal to an average number of 1's.

14. The method of claim 1, further comprising:
adjusting a voltage threshold V_{THR} to control input of the output circuit to cause the output circuit to output the random binary stream such that the random binary stream outputs an average number of 0's that is unequal to an average number of 1's.

15. The method of claim 1, further comprising:
emitting the first series of photons from a source in thermal equilibrium.

16. The method of claim 15, wherein the source comprises one or more of a light-emitting diode (LED), a pulsed laser, and a combination thereof.

17. The method of claim 1, further comprising
digitizing, with an analog to digital converter (ADC), one or more of the first series of electrical pulses, and the random binary stream.

18. The method of claim 1, further comprising:
varying a dead time of receiving, at the SPAD, a first series of photons, wherein the first series of photons comprise a first random time interval between an arrival of each photon in the first series of photons.

19. The method of claim 1, further comprising:
receiving, at a second single-photon avalanche diode (SPAD), a second series of photons;
converting, by the second SPAD, the second series of photons into a second series of electrical pulses comprising a second random time interval between each pulse of the second series of electrical pulses; and
outputting, by the output circuit, a random binary stream based at least in part on the first series of electrical pulses and the second series of electrical pulses, wherein the output circuit comprises one or more of a NOT gate, an AND gate, a NAND gate, an OR gate, a NOR gate, an XOR gate, an XNOR gate, and a combinations thereof.

20. A quantum random number generator, comprising:
one or more single-photon avalanche diodes (SPADs), each of the SPADS configured to receive a corresponding series of photons;
one or more quenching circuits in communication with each corresponding one or more SPADs, the one or more quenching circuits configured to convert the corresponding series of photons into corresponding series of electrical pulses, each corresponding series of electrical pulses comprising corresponding random time intervals between each pulse of corresponding series of electrical pulses; and
an output circuit in communication with one or more quenching circuits, the output circuit configured to output a random binary stream based at least in part on the corresponding series of electrical pulses.
